(19) United States
(12) Patent Application Publication
(10) Pub. No.: US 2020/0354829 A1
(43) Pub. Date: Nov. 12, 2020

(54) Methods and apparatuses for forming graphene

(71) Applicant: Samsung Electronics Co., Ltd., Suwon-si (KR)

(72) Inventors: Hyunjae SONG, Hwaseong-si (KR); Eunkyu LEE, Yongin-si (KR); Changseok LEE, Seoul (KR); Changhyun KIM, Seoul (KR); Kyung-Eun BYUN, Seongnam-si (KR); Keunwook SHIN, Yongin-si (KR); Hyeonjin SHIN, Suwon-si (KR)

(73) Assignee: Samsung Electronics Co., Ltd., Suwon-si (KR)

(21) Appl. No.: 16/860,465

(22) Filed: Apr. 28, 2020

(30) Foreign Application Priority Data
May 7, 2019 (KR) 10-2019-0053240

(51) Int. Cl. C23C 16/26; H01L 21/285; C23C 16/50; C23C 16/02

(52) U.S. Cl. CPC C23C 16/26; H01L 21/28556; H01L 21/76841; C23C 16/0272; C23C 16/50

(57) ABSTRACT

A method of forming graphene includes providing, in a reaction chamber, a non-catalyst substrate at least partially including a material that does not catalyze growth of graphene, and directly growing graphene on a surface of the non-catalyst substrate based on injecting a reaction gas into the reaction chamber. The reaction gas includes a carbon source having an ionization energy equal to or less than about 10.6 eV in a plasma-enhanced chemical vapor deposition (PECVD) process.

### CROSS-REFERENCE TO RELATED APPLICATION

This application claims the benefit of Korean Patent Application No. 10-2019-0053240, filed on May 7, 2019, in the Korean Intellectual Property Office, the disclosure of which is incorporated herein in its entirety by reference.

### BACKGROUND

### 1. Field

The present disclosure relates to methods of forming graphene, and more particularly, to methods of directly forming graphene on non-catalyst substrates.

### 2. Description of the Related Art

To address the problems of the increasing resistance caused by the reduced width of metal wiring and the need for development of new metal barrier materials in the field of semiconductor devices, research into graphene is actively conducted. Graphene is a material having a hexagonal honeycomb structure in which carbon atoms are connected two-dimensionally and has a very small, atomic-scale thickness. Graphene has higher electric mobility and excellent heat characteristics compared to silicon (Si), and is also chemically stable and has a broad surface area.

### SUMMARY

Provided are methods of directly forming graphene on non-catalyst substrates.

According to some example embodiments, a method of forming graphene may include providing, in a reaction chamber, a non-catalyst substrate at least partially including a material that does not catalyze growth of graphene, and directly growing graphene on a surface of the non-catalyst substrate based on injecting a reaction gas into the reaction chamber, the reaction gas including a carbon source having an ionization energy equal to or less than about 10.6 eV in a plasma-enhanced chemical vapor deposition (PECVD) process.

The growing of the graphene may be performed at a processing temperature equal to or less than about 400° C.

The plasma may be generated based on using at least one radio frequency (RF) plasma generator or at least one microwave (MW) plasma generator.

The non-catalyst substrate may include at least one of a Group IV semiconductor material, a semiconductor compound, or an insulating material.

The non-catalyst substrate may further include a dopant.

The non-catalyst substrate may include a material that includes a combination of at least two elements selected from among Si, Ge, C, Zn, Cd, Al, Ga, In, B, C, N, P, S, Se, As, Sb, or Te.

The non-catalyst substrate may include at least one of an oxide, a nitride, a carbide of at least one of Si, Ni, Al, W, Ru, Co, Mn, Ti, Ta, Au, Hf, Zr, Zn, Y, Cr, Cu, Mo, or Gd, or a derivative thereof.

The carbon source may include a hydrocarbon which is in a liquid state at room temperature.

The carbon source may include at least one of a precursor including a molecular precursor, the molecular precursor including one or more aromatic molecular rings, a precursor including a molecule having one or more aromatic molecular rings and a functional group, a molecular precursor including three or more aliphatic carbon bonds, or a precursor including a functional group.

The carbon source may include at least one of benzene, toluene, meta-xylene, propane, propene, butane, hexane, octane, cyclohexane, oxygen, nitrogen, sulfur, or phosphor.

The reaction gas may further include at least one of an inert gas or a reducing gas.

The graphene may include crystals having a crystal size of about 0.5 nm to about 100 nm.

The directly growing the graphene may be performed at a pressure that is equal to or less than about 10 Torr.

The method may further include performing a pre-treatment on a surface of the non-catalyst substrate.

The performing the pre-treatment may include forming at least one of charges or activation sites that induce adsorption of active carbon radicals on the surface of the non-catalyst substrate.

The performing the pre-treatment may include injecting a pre-treatment gas into the reaction chamber.

The pre-treatment gas may include at least one of inert gas, hydrogen, nitrogen, chlorine, fluorine, ammonia, or derivatives thereof.

An apparatus may include a plasma enhanced chemical vapor deposition machine configured to perform the method.

The performing the pre-treatment may include supplying a bias power to the non-catalyst substrate, the bias power ranging from about 1 W to about 300 W.

According to some example embodiments, a method of forming graphene may include pre-treating a surface of a non-catalyst substrate at least partially including a material that does not catalyze growth of graphene, pre-treating including forming at least one of charges or activation sites that induce adsorption of active carbon radicals on the surface of the non-catalyst substrate; and directly growing graphene on the pre-treated surface of the non-catalyst substrate based on injecting a reaction gas into a reaction chamber in which the non-catalyst substrate is provided, the reaction gas including a carbon source having an ionization energy equal to or less than about 10.6 eV in a plasma-enhanced chemical vapor deposition (PECVD) process.

The pre-treating the non-catalyst substrate may include placing the non-catalyst substrate including the pre-treated surface in the reaction chamber, injecting a pre-treatment gas into the reaction chamber, and supplying a bias power to the non-catalyst substrate, the bias power ranging from about 1 W to about 300 W.

The pre-treatment gas may include at least one of inert gas, hydrogen, nitrogen, chlorine, fluorine, ammonia, or derivatives thereof.

The growing of the graphene may be performed at a processing temperature equal to or less than about 400° C.

The plasma may be generated based on using at least one radio frequency (RF) plasma generator or at least one microwave (MW) plasma generator.

The non-catalyst substrate may include at least one of a Group IV semiconductor material, a semiconductor compound, or an insulating material.

The non-catalyst substrate may further include a dopant.

The non-catalyst substrate may include a material that includes a combination of at least two elements selected from among Si, Ge, C, Zn, Cd, Al, Ga, In, B, C, N, P, S, Se, As, Sb, and Te.

The non-catalyst substrate may include at least one of an oxide, a nitride, a carbide of at least one of Si, Ni, Al, W, Ru, Co, Mn, Ti, Ta, Au, Hf, Zr, Zn, Y, Cr, Cu, Mo, or Gd, or a derivative thereof.

The carbon source may include a hydrocarbon which is in a liquid state at room temperature.

The carbon source may include at least one of a precursor including a molecular precursor, the molecular precursor including one or more aromatic molecular rings, a precursor including a molecule having one or more aromatic molecular rings and a functional group, a molecular precursor including three or more aliphatic carbon bonds, or a precursor including a functional group.

The carbon source may include at least one of benzene, toluene, meta-xylene, propane, propene, butane, hexane, octane, cyclohexane, oxygen, nitrogen, sulfur, or phosphor.

The reaction gas may further include at least one of an inert gas or a reducing gas.

The graphene may include crystals having a crystal size of about 0.5 nm to about 100 nm.

The directly growing the graphene may be performed at a pressure that is equal to or less than about 10 Torr.

An apparatus may include a plasma enhanced chemical vapor deposition machine configured to perform the method.

### BRIEF DESCRIPTION OF THE DRAWINGS

These and/or other aspects will become apparent and more readily appreciated from the following description of some example embodiments, taken in conjunction with the accompanying drawings in which:

FIGS. 1A, 1B, and 1C are views of a method of forming graphene, according to some example embodiments;

FIG. 2 is a diagram illustrating ionization energy of each hydrocarbon according to some example embodiments;

FIGS. 3A and 3B are views illustrating a result of the Raman analysis of graphene grown using different carbon sources according to some example embodiments;

FIGS. 4A, 4B, 4C, and 4D are views of a method of forming graphene, according to some example embodiments; and

FIG. 5 is a cross-sectional view of an apparatus for forming graphene according to some example embodiments.

### DETAILED DESCRIPTION

Reference will now be made in detail to example embodiments, some example embodiments of which are illustrated in the accompanying drawings, wherein like reference numerals refer to like elements throughout and sizes of constituent elements may be exaggerated for convenience of explanation and the clarity of the specification. In this regard, some example embodiments may have different forms and should not be construed as being limited to the descriptions set forth herein. Accordingly, some example embodiments are merely described below, by referring to the figures, to explain aspects of the present description. As used herein, the term “and/or” includes any and all combinations of one or more of the associated listed items (e.g., A, B, and C). Expressions such as “at least one of,” when preceding a list of elements, modify the entire list of elements and do not modify the individual elements of the list. For example, “at least one of A, B, and C,” and “at least one of A, B, or C” may be construed as covering any one of the following combinations: A; B; A and B; A and C; B and C; and A, B, and C.”

It will also be understood that when an element is referred to as being “on” or “above” another element, the element may be in direct contact with the other element or other intervening elements may be present. An expression used in the singular encompasses the expression of the plural, unless it has a clearly different meaning in the context. It should be understood that, when a part “comprises” or “includes” an element in the specification, unless otherwise defined, other elements are not excluded from the part and the part may further include other elements. The use of the terms “the” and similar referents in the context are to be construed to cover both the singular and the plural.

In some example embodiments, graphene (nanocrystalline graphene) and a method of directly growing graphene on a surface of a non-catalyst substrate in a plasma-enhanced chemical vapor deposition (PECVD) method will be described.

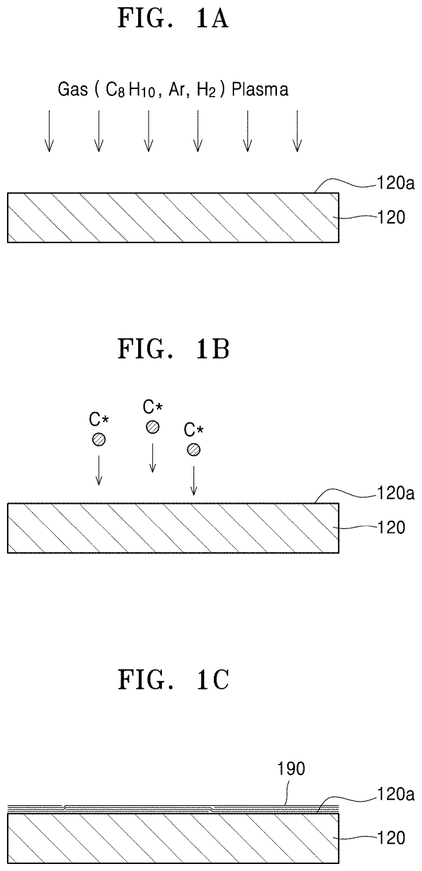

FIGS. 1A, 1B, and 1C are views of a method of forming graphene, according to some example embodiments.

Referring to FIG. 1A, a reaction gas for growing graphene 190 (e.g., a layer of graphene) (FIG. 1C) is injected into a reaction chamber (not shown) in which a non-catalyst substrate 120 is provided (e.g., located), and power to generate plasma is applied (e.g., supplied).

First, the non-catalyst substrate 120 is provided in the reaction chamber (e.g., placed in the reaction chamber). The non-catalyst substrate 120 includes a substrate formed of (e.g., at least partially comprising) a material that does not catalyze growth of graphene (e.g., is configured to not catalyze growth of graphene). Accordingly, the non-catalyst substrate 120 may be configured to not catalyze growth of graphene on an upper surface, surface 120a, of the non-catalyst substrate 120. For example, the non-catalyst substrate 120 may include a substrate that does not include a metal. The non-catalyst substrate 120 may include at least one of a Group IV semiconductor material, a semiconductor compound, or an insulating material. In detail, the Group IV semiconductor material may include Si, Ge, or Sn. The semiconductor compound may include, for example, a material that includes a combination of at least two elements selected from among Si, Ge, C, Zn, Cd, Al, Ga, In, B, C, N, P, S, Se, As, Sb, or Te.

The insulating material may include at least one of Si, Al, Hf, Zr, Zn, Ti, Ta, W, or Mn or at least one of an oxide, a nitride, a carbide of at least one of Si, Ni, Al, W, Ru, Co, Mn, Ti, Ta, Au, Hf, Zr, Zn, Y, Cr, Cu, Mo, or Gd, or a derivative thereof. Accordingly, the non-catalyst substrate 120 may include at least one of an oxide, a nitride, a carbide of at least one of Si, Ni, Al, W, Ru, Co, Mn, Ti, Ta, Au, Hf, Zr, Zn, Y, Cr, Cu, Mo, or Gd, or a derivative thereof. The at least one of the oxide, nitride, carbide, or the derivative thereof may further include H. The non-catalyst substrate 120 may further include a dopant. The materials of the non-catalyst substrate 120 described above are examples, and the non-catalyst substrate 120 may be formed of (e.g., at least partially comprise) a material that does not catalyze the growth of graphene.

Next, a reaction gas is injected into the reaction chamber to grow the graphene 190. The reaction gas may include a carbon source supplying carbon to grow the graphene 190. The carbon source may be a hydrocarbon having ionization energy equal to or less than about 10.6 eV, for example between about 1.2 eV and about 10.6 eV.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

The carbon source may include a liquid precursor, which is in a liquid state at room temperature. The carbon source may include a hydrocarbon which is in a liquid state at room temperature (e.g., about 20° C. to about 25° C.). For example, the liquid precursor may be a molecular precursor including one or more aromatic molecular rings such as benzene, toluene, xylene, mesitylene, or the like or a precursor including a molecule having one or more aromatic molecular rings, such as chlorobenzene or anisole (methyl phenyl ether), and a functional group. In some example embodiments, the carbon source may include a molecular precursor including three or more aliphatic carbon bonds such as propane, propene, butane, hexane, octane, cyclohexane, or the like and a precursor including a functional group such as oxygen, nitrogen, sulfur, or the like. In some example embodiments, the carbon source may include at least one of benzene, toluene, meta-xylene, propane, propene, butane, hexane, octane, cyclohexane, oxygen, nitrogen, sulfur, or phosphor. However, these are merely examples, and any hydrocarbon having ionization energy of about 10.6 eV or less (e.g., between about 1.2 eV and about 10.6 eV) may be used.

The reaction gas may further include at least one of an inert gas or a hydrogen gas. The inert gas may include, for example, at least one of argon gas, neon gas, nitrogen gas, helium gas, krypton gas, or xenon gas. FIG. 1A shows an example in which the reaction gas includes a carbon source, inert gas, and hydrogen gas, wherein meta-xylene is used as the carbon source and argon gas is used as the inert gas. A mixing ratio of the reaction gas injected into the reaction chamber may be variously modified according to the growth conditions of the graphene.

Next, power for generating plasma is applied (e.g., supplied) to the reaction chamber from a plasma power supply (not shown). Here, the power for generating plasma may be about 10 W to about 4,000 W. However, the power is not limited thereto.

As the plasma power supply, for example, a radio frequency (RF) plasma generator or a microwave (MW) plasma generator, may be used. Restated, the plasma-enhanced chemical vapor deposition (PECVD) process may utilize a plasma that may be generated based on using at least one radio frequency (RF) plasma generate or at least one microwave (MW) plasma generator. To grow the graphene 190, the RF plasma generator may generate RF plasma having a frequency range of, for example, about 3 MHz to about 100 MHz, and the MW plasma generator may generate MW plasma having a frequency range of, for example, about 0.7 to about 2.5 GHz. The frequency ranges above are examples, and other frequency ranges may also be used. Meanwhile, a plurality of RF plasma generators or a plurality of MW plasma generators may be used as a plasma power supply.

When power for generating plasma is applied (e.g., supplied) from the plasma power supply into the reaction chamber, an electric field may be induced in the reaction chamber. When an electric field is induced after the reaction gas is injected, plasma for growing graphene is formed.

When growing graphene by using plasma, a mixing ratio of reaction gases injected into the reaction chamber, that is, a volume ratio of a carbon source, an inert gas, and a hydrogen gas may be, for example, approximately about 1:about 0.01 to about 5,000:about 0 to about 300. The volume ratio of the carbon source, the inert gas, and the hydrogen gas included in the reaction gas may be appropriately adjusted according to different growth conditions.

A processing temperature for growing graphene may be equal to or less than about 400° C., which is lower than a temperature used in a chemical vapor deposition (CVD) process. For example, a processing temperature in the reaction chamber may be about 180° C. to about 400° C. A processing pressure for growing graphene may be equal to or less than about 10 Torr. For example, the processing pressure may be about 0.001 Torr to about 10 Torr. However, the above-described processing pressure is an example, and other processing pressures may also be used.

Referring to FIG. 1B, active carbon radicals (C*) are generated by plasma of a reaction gas, in which a carbon source, an inert gas, and a hydrogen gas are mixed and are adsorbed onto a surface of the non-catalyst substrate 120. As the carbon source has ionization energy of about 10.6 eV, active carbon radicals (C*) are easily generated at a relatively low temperature, and the active carbon radicals (C*) are adsorbed onto the surface of the non-catalyst substrate 120 to activate the surface of the non-catalyst substrate 120. Also, as plasma of the inert gas continuously induces activation of the non-catalyst substrate 120, adsorption of the active carbon radicals (C*) onto the surface 120a of the non-catalyst substrate 120 may be accelerated. Moreover, due to the relatively low ionization energy, graphene may be directly grown on a substrate without a catalyst.

Referring to FIG. 1C, as adsorption of the active carbon radicals (C*) onto the surface 120a of the non-catalyst substrate 120 is accelerated even at a low temperature, the graphene 190 may be grown on the surface of the non-catalyst substrate 120. According to some example embodiments, as the ionization energy of the carbon source is as low as 10.6 eV, active carbon radicals may be easily generated even at a low temperature, for example, at a temperature equal to or less than about 400° C. (e.g., about 180° C. to about 400° C.). Thus, the graphene 190 may be directly grown on the surface 120a of the non-catalyst substrate 120. The grown graphene may include nano-scale crystals. For example, the graphene 190 may include crystals having a size equal to or less than about 100 nm. In detail, the graphene 190 may include crystals having a size of about 0.5 nm to about 100 nm.

Accordingly, as shown in FIGS. 1A-C, a method of forming graphene according to some example embodiments may include providing, in a reaction chamber, a non-catalyst substrate 120 at least partially including a material that does not catalyze growth of graphene; and directly growing graphene 190 on a surface 120a of the non-catalyst substrate 120 (FIG. 1C) based on injecting a reaction gas into the reaction chamber (FIG. 1A), the reaction gas including a carbon source having an ionization energy equal to or less than about 10.6 eV in a plasma-enhanced chemical vapor deposition (PECVD) process.

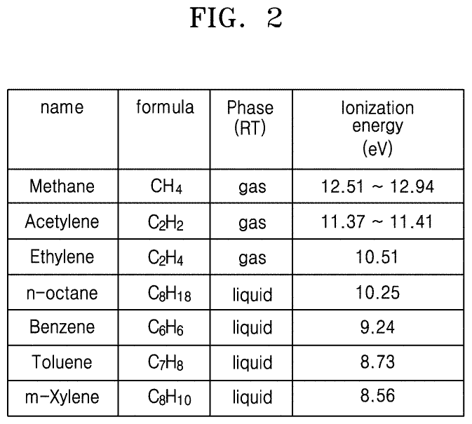

FIG. 2 is a diagram illustrating ionization energy of each hydrocarbon according to some example embodiments. As illustrated in FIG. 2, a carbon source having relatively low ionization energy may typically be in a liquid state at room temperature. In addition, hydrocarbons having ionization energy equal to or less than about 10.6 eV may be benzene, specifically, benzene that is substituted with at least one alkyl group. While benzene, toluene, and meta-xylene are illustrated as hydrocarbons having ionization energy of 10.6 eV or lower in FIG. 2, the hydrocarbons are not limited thereto. Any other hydrocarbons having ionization energy of 10.6 eV or lower may also be applied.

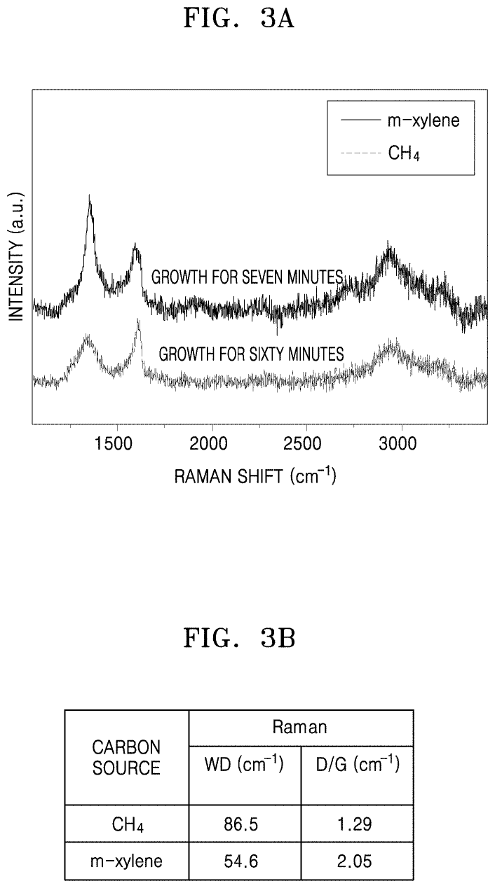

FIGS. 3A and 3B are views illustrating a result of the Raman analysis of graphene grown using different carbon sources according to some example embodiments. In general, in a Raman spectrum, a peak G may be present around (e.g., “at about”) 1590 cm⁻¹, a peak D may be present around 1350 cm⁻¹, and a 2D peak may be present around 2700 cm⁻¹.

As illustrated in FIG. 3A, the graphene grown by using meta-xylene for seven minutes had a graphene structure of a strong intensity. However, the graphene grown by using methane for sixty minutes had a graphene structure of a weak intensity. That is, it is shown that by using a hydrocarbon having low ionization energy, graphene may be easily grown even for a short period of time at a low temperature.

In addition, as illustrated in FIG. 3B, even when a width WD of peak D of the graphene grown by using meta-xylene is less than a width WD of peak D of the graphene grown by using methane, a ratio (D/G) of the peak D with respect to peak G of the graphene grown using meta-xylene was greater than a ratio (D/G) of the peak D with respect to peak G of the graphene grown using methane. This may indicate that graphene having better crystallinity may be grown by using a carbon source having relatively low ionization energy even at a low temperature (e.g., meta-xylene) than a carbon source having relatively high ionization energy (e.g., methane).

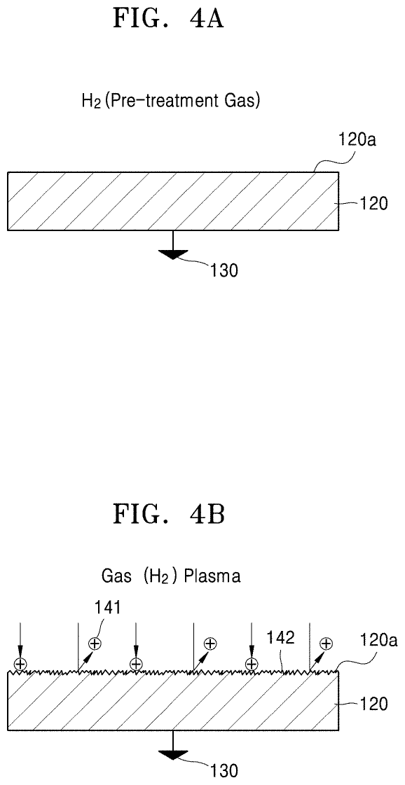

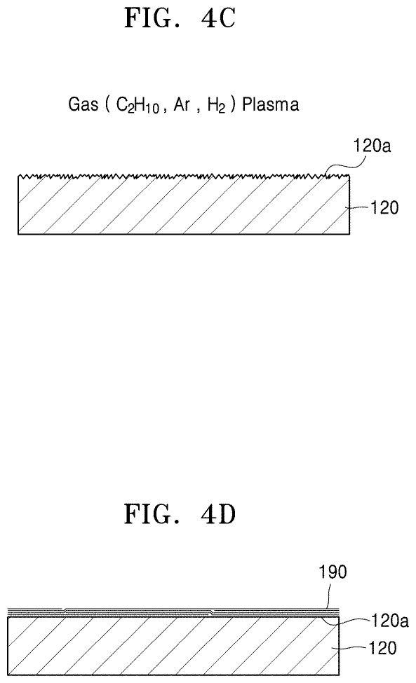

FIGS. 4A, 4B, 4C, and 4D are views of a method of forming graphene, according to some example embodiments.

Referring to FIG. 4A, before growing graphene, a pre-treatment process may be performed on a surface 120a of the non-catalyst substrate 120 based on using a reducing gas. The pre-treatment process may be performed at a low temperature. For example, the pre-treatment process of the non-catalyst substrate 120 may be performed at a processing temperature equal to or lower than about 400° C. (e.g., between about 180° C. and about 400° C.). In addition, a processing pressure at which a pre-treatment process of the non-catalyst substrate 120 is performed may be lower than, for example, a processing pressure at which a graphene growth process which will be described later is performed.

The pre-treatment process of the non-catalyst substrate 120 may be performed to remove impurities, oxygen, or the like remaining on the surface of the non-catalyst substrate 120. In some example embodiments, in the pre-treatment process, charges or activation sites that each enable effective adsorption of active carbon radicals onto a surface 120a of the non-catalyst substrate 120 may be generated. Hereinafter, a method of generating charges and activation sites will be described.

First, the non-catalyst substrate 120 for growing the graphene 190 is provided (e.g., located, positioned, or the like) inside a reaction chamber. The non-catalyst substrate 120 may refer to a substrate formed of a material that does catalyze growth of graphene. For example, the non-catalyst substrate 120 may include at least one of a Group IV semiconductor material, a semiconductor compound, or an insulating material. In detail, the Group IV semiconductor material may include Si, Ge, or Sn. The semiconductor compound may include, for example, a material in which at least two elements selected from among Si, Ge, C, Zn, Cd, Al, Ga, In, B, C, N, P, S, Se, As, Sb, or Te are combined.

The insulating material may include at least one of Si, Al, Hf, Zr, Zn, Ti, Ta, W, or Mn or at least one of an oxide, a nitride, a carbide of at least one of Si, Ni, Al, W, Ru, Co, Mn, Ti, Ta, Au, Hf, Zr, Zn, Y, Cr, Cu, Mo, or Gd, or a derivative thereof. The at least one of the oxide, nitride, carbide, or the derivative thereof may further include H. The non-catalyst substrate 120 may further include a dopant.

Next, referring to FIG. 4A, a gas for pre-treatment of the non-catalyst substrate 120 (e.g., a pre-treatment gas) is injected into the reaction chamber. Here, a reducing gas may be used as a pre-treatment gas. The reducing gas may include, for example, at least one of hydrogen, nitrogen, chlorine, fluorine, ammonia, or derivatives thereof. However, the reducing gas is not limited thereto. In addition, an inert gas may be additionally injected into the reaction chamber in addition to the reducing gas. The inert gas may include, for example, at least one of argon gas, neon gas, nitrogen gas, helium gas, krypton gas, or xenon gas. In some example embodiments, the inert gas is used in place of the reducing gas. Referring to FIG. 4A, hydrogen gas is used as the reducing gas.

Next, a bias (e.g., bias power) is applied (e.g., supplied) to the non-catalyst substrate 120 via a bias supply 130 (e.g., bias power supply). A bias applied to the non-catalyst substrate 120 may be, for example, an RF bias or a direct-current (DC) bias. Accordingly, a certain (+) bias voltage or a (−) bias voltage may be applied to the non-catalyst substrate 120. To this end, bias power having a certain amount may be applied to the non-catalyst substrate 120. For example, bias power ranging from about 1 W to about 300 W may be applied to the non-catalyst substrate 120 in a pre-treatment process of the non-catalyst substrate 120. However, this is merely an example, and the bias power applied to the non-catalyst substrate 120 may vary.

Referring to FIG. 4B, while a bias is applied to the non-catalyst substrate 120, when plasma power is applied into the reaction chamber, gas plasma (for example, hydrogen plasma) may be generated in the reaction chamber. The bias power applied to the non-catalyst substrate 120 may be about 1 W to about 300 W. When gas plasma is generated in the reaction chamber while a bias is applied to the non-catalyst substrate 120 as described above, at least one of charges 141 or activation sites 142 may be formed on the surface 120a of the non-catalyst substrate 120.

For example, while (e.g., simultaneously with) a (−) bias voltage is applied to the non-catalyst substrate 120, (+) charges 141 may be formed on the surface 120a of the non-catalyst substrate 120. While a (+) bias voltage is applied to the non-catalyst substrate 120, (−) charges 141 may be formed on the surface 120a of the non-catalyst substrate 120. The activation sites 142 may be formed as the charges 141 move toward the non-catalyst substrate 120 to collide with the surface 120a of the non-catalyst substrate 120. The activation sites 142 may have, for example, roughness or defects. In FIG. 4B, roughness is illustrated as an example of the activation sites 142.

The charges 141 and/or the activation sites 142 may enable active carbon radicals to be effectively adsorbed onto the surface 120a of the non-catalyst substrate 120, and graphene may be directly grown on the surface 120a of the non-catalyst substrate 120 even at a low temperature of 400° C. or lower. Accordingly, the pre-treatment process may include forming at least one of charges 141 or activation sites that induce adsorption of active carbon radicals on the surface 120a of the non-catalyst substrate 120.

After the pre-treatment process of the non-catalyst substrate 120 is completed, as illustrated in FIG. 4C, a reaction gas for growing the graphene 190 is injected into the reaction chamber and power for generating plasma is applied into the reaction chamber.

In detail, first, a reaction gas is injected into the reaction chamber to grow the graphene 190. The reaction gas may include a carbon source gas, an inert gas, and a hydrogen gas. In some example embodiments, the reaction gas may not include a hydrogen gas.

A carbon source may be a hydrocarbon having ionization energy of 10.6 eV or lower, and the hydrocarbon may include a liquid precursor, which is in a liquid state at room temperature. In addition, the liquid precursor may be a molecular precursor including one or more aromatic molecular rings such as benzene, toluene, xylene, mesitylene, or the like or a precursor including a molecule having one or more aromatic molecular rings, such as chlorobenzene or anisole, and a functional group. In some example embodiments, the carbon source may include a molecular precursor including three or more aliphatic carbon bonds such as propane, propene, butane, hexane, octane, cyclohexane, or the like and a precursor including a functional group such as oxygen, nitrogen, sulfur, or the like. However, these are merely examples, and any hydrocarbon having ionization energy of 10.6 eV or less may be used.

The inert gas may include, for example, at least one of argon gas, neon gas, nitrogen gas, helium gas, krypton gas, or xenon gas. In FIG. 4C, some example embodiments in which acetylene gas is used as a carbon source and argon gas is used as an inert gas is illustrated.

Next, power for generating plasma is applied to the reaction chamber from a plasma power supply. Here, the power for generating plasma may be approximately 10 W to 4000 W. As the plasma power supply, for example, at least one RF plasma generator or at least one MW plasma generator may be used. A processing temperature may be about 180° C. to about 400° C. For example, the processing pressure may be about 0.001 Torr to about 10 Torr.

When power for generating plasma is applied from the plasma power supply into the reaction chamber, an electric field may be induced in the reaction chamber. When an electric field is induced after the reaction gas is injected, plasma for growing the graphene 190 is formed.

From among the reaction gas, plasma of the inert gas generates active carbon radicals from the carbon source. The active carbon radicals are adsorbed onto a surface the surface 120a of the non-catalyst substrate 120 to activate the surface 120a of the non-catalyst substrate 120. Also, plasma of the inert gas continuously induces activation of the non-catalyst substrate 120, and charges and activation sites may accelerate adsorption of the active carbon radicals on the surface 120a of the non-catalyst substrate 120. The ionization energy of the carbon source is as low as 10.6 eV, and thus, active carbon radicals may be easily generated also at a low temperature, for example, about 180° C. to about 400° C. Thus, the graphene 190 may be directly grown on the surface 120a of the non-catalyst substrate 120.

Referring to FIG. 4D, as adsorption of the active carbon radical on the surface 120a of the non-catalyst substrate 120 is accelerated, the graphene 190 may be grown on the surface 120a of the non-catalyst substrate 120 in a short period of time.

The graphene 190 may be grown on the surface 120a of the non-catalyst substrate 120 at a relatively high speed. For example, the graphene 190 having a desired thickness may be grown in a relatively short period of time, for example, thirty minutes or less (specifically, ten minutes or less). As described above, the graphene 190 having a desired thickness may be formed on the surface 120a of the non-catalyst substrate 120 in a relatively short period of time. The graphene 190 formed as described above may have a single-layer or multi-layer structure.

According to some example embodiments, a pre-treatment is performed on a surface of the non-catalyst substrate 120 by using a reducing gas (or a mixture gas of a reducing gas and an inert gas), and then the graphene 190 is grown on the pre-treated surface of the non-catalyst substrate 120 to thereby obtain the graphene 190 having a relatively high quality even at a low temperature.

Accordingly, as shown in FIGS. 4A-4D, a method of forming graphene 190 according to some example embodiments may include pre-treating a surface 120a of a non-catalyst substrate 120 at least partially including a material that does not catalyze growth of graphene, where the pre-treating includes forming at least one of charges or activation sites that induce adsorption of active carbon radicals on the surface of the non-catalyst substrate (FIGS. 4A-4B), and directly growing graphene 190 on the pre-treated surface 120a of the non-catalyst substrate 120 (FIG. 4D) based on injecting a reaction gas into the reaction chamber in which the non-catalyst substrate is provided (FIG. 4C), the reaction gas including a carbon source having an ionization energy equal to or less than about 10.6 eV in a plasma-enhanced chemical vapor deposition (PECVD) process.

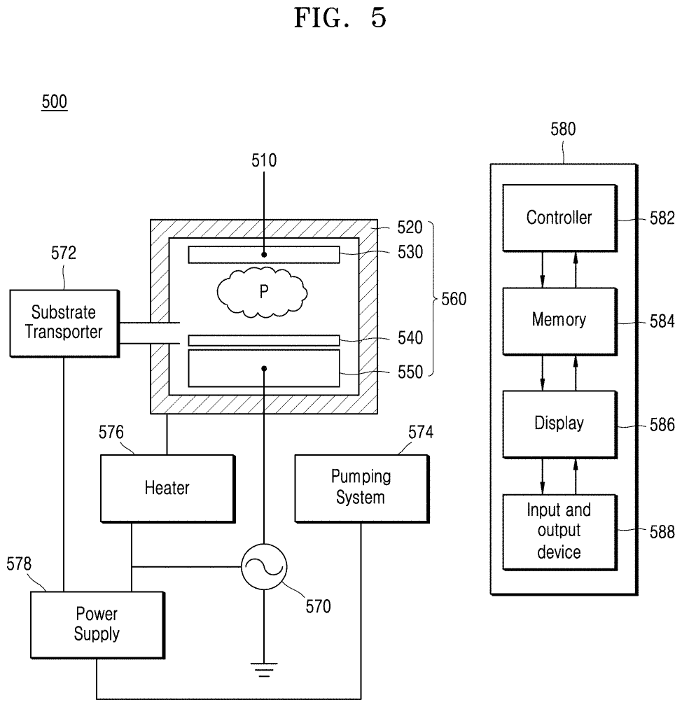

FIG. 5 is a cross-sectional view of an apparatus 500 for forming graphene according to some example embodiments. The apparatus 500 may perform any of the methods of forming graphene according to any of the example embodiments. The apparatus 500 may be, in some example embodiments, a plasma enhanced chemical vapor deposition machine configured to perform any of the methods of forming graphene according to any of the example embodiments.

Referring to FIG. 5, an apparatus 500 may include a gas supply 510, a process chamber 560, a plasma generation unit 570, a substrate transporter 572, a pumping system 574, a heater 576, a power supply 578, and an operation station 580. The process chamber 560 may include a chamber housing 520, an upper electrode 530 in the chamber housing 520, and a substrate support 550 in the chamber housing 520. The upper electrode 530 may be connected to a gas supply 510 with conduits and gas flow controllers for providing reaction gases into the process chamber 560. The substrate support 550 may be an electrostatic chuck, but is not limited thereto.

A substrate transporter 572, such as a robot arm, may transport a substrate 540 into and out of the process chamber 560. The process chamber 560 may include a gate valve that opens when the substrate transporter 572 transports the substrate 540 into or out of the process chamber 560 and closes when the process chamber 560 performs operations (e.g., vacuum processes). A heater 576 (e.g., electric heater) may control the temperature of the substrate support 550, inner wall of process chamber 560, and upper electrode 530. The plasma generation unit 570 may be a RF power generator and may be connected to the substrate support 550 and may be used to generate a plasma P of a reaction gas in the process chamber 560. In some example embodiments, a microwave power supply may be used to generate the plasma P in the process chamber 560. A pumping system 574 connected to the process chamber 560 may create a vacuum in the process chamber 560. A power supply 578 (e.g., circuit) may provide electrical power to the apparatus 500.

The operation station 580 may control operations of the apparatus 500. The operation station 580 may include a controller 582, a memory 584, a display 586 (e.g., monitor), and an input and output device 588. The memory 584 may include a nonvolatile memory, such as a flash memory, a phase-change random access memory (PRAM), a magneto-resistive RAM (MRAM), a resistive RAM (ReRAM), or a ferro-electric RAM (FRAM), and/or a volatile memory, such as a static RAM (SRAM), a dynamic RAM (DRAM), or a synchronous DRAM (SDRAM). The input and output device 588 may be a keyboard and/or a touch screen.

The memory 584 may store an operating system and may store recipe instructions that include settings (e.g., gas flow rates, temperature, time, power, pressure, etc.) for different manufacturing processes performed by the apparatus 500. The memory 584 may store recipe instructions for forming a graphene product (e.g., graphene) on the substrate 540 according to one or more of the embodiments in FIGS. 1A-1C and/or 4A-4D of the present application.

The controller 582 may be, a central processing unit (CPU), a controller, or an application-specific integrated circuit (ASIC), that when, executing recipe instructions stored in the memory 584 (for one or more of the embodiments in FIGS. 1A-1C and/or 4A-4D) configures the controller 582 as a special purpose controller that operates apparatus 500 to form a graphene according to example embodiments on the substrate 540.

The controller 582 may be included in, may include, and/or may be implemented by, one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. In some example embodiments, the processing circuitry may include a non-transitory computer readable storage device, for example a solid state drive (SSD), storing a program of instructions, and a processor configured to execute the program of instructions to implement the functionality of the controller 582.

According to some example embodiments, graphene may be easily grown even at a low temperature by using a carbon source having low ionization energy. The charges and activation sites generated in the pre-treatment process may accelerate growth of graphene to thereby form the graphene in a short period of time.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A method of forming graphene, the method comprising:
providing, in a reaction chamber, a non-catalyst substrate at least partially including a material that does not catalyze growth of graphene; and
directly growing graphene on a surface of the non-catalyst substrate based on injecting a reaction gas into the reaction chamber, the reaction gas including a carbon source having an ionization energy equal to or less than about 10.6 eV in a plasma-enhanced chemical vapor deposition (PECVD) process.

2. The method of claim 1, wherein the growing of the graphene is performed at a processing temperature equal to or less than about 400° C.

3. The method of claim 1, wherein the plasma-enhanced chemical vapor deposition (PECVD) process utilizes a plasma that is generated based on using at least one radio frequency (RF) plasma generator or at least one microwave (MW) plasma generator.

4. The method of claim 1, wherein the non-catalyst substrate includes at least one of a Group IV semiconductor material, a semiconductor compound, or an insulating material.

5. The method of claim 4, wherein the non-catalyst substrate further includes a dopant.

6. The method of claim 1, wherein the non-catalyst substrate includes a material that includes a combination of at least two elements selected from among Si, Ge, C, Zn, Cd, Al, Ga, In, B, C, N, P, S, Se, As, Sb, or Te.

7. The method of claim 1, wherein the non-catalyst substrate includes at least one of
an oxide,
a nitride,
a carbide of at least one of Si, Ni, Al, W, Ru, Co, Mn, Ti, Ta, Au, Hf, Zr, Zn, Y, Cr, Cu, Mo, or Gd, or
a derivative thereof.

8. The method of claim 1, wherein the carbon source includes a hydrocarbon which is in a liquid state at room temperature.

9. The method of claim 1, wherein the carbon source includes at least one of
a precursor including a molecular precursor, the molecular precursor including one or more aromatic molecular rings,
a precursor including a molecule having one or more aromatic molecular rings and a functional group,
a molecular precursor including three or more aliphatic carbon bonds, or
a precursor including a functional group.

10. The method of claim 9, wherein the carbon source includes at least one of benzene, toluene, meta-xylene, propane, propene, butane, hexane, octane, cyclohexane, oxygen, nitrogen, sulfur, or phosphor.

11. The method of claim 1, wherein the reaction gas further includes at least one of an inert gas or a reducing gas.

12. The method of claim 1, wherein the graphene includes crystals having a crystal size of about 0.5 nm to about 100 nm.

13. The method of claim 1, wherein the directly growing the graphene is performed at a pressure that is equal to or less than about 10 Torr.

14. The method of claim 1, further comprising:
performing a pre-treatment on the surface of the non-catalyst substrate.

15. The method of claim 14, wherein, the performing the pre-treatment includes forming at least one of charges or activation sites that induce adsorption of active carbon radicals on the surface of the non-catalyst substrate.

16. The method of claim 14, wherein the performing the pre-treatment includes injecting a pre-treatment gas into the reaction chamber.

17. The method of claim 16, wherein the pre-treatment gas includes at least one of inert gas, hydrogen, nitrogen, chlorine, fluorine, ammonia, or derivatives thereof.

18. The method of claim 16, wherein the performing the pre-treatment includes supplying a bias power to the non-catalyst substrate, the bias power ranging from about 1 W to about 300 W.

19. An apparatus, comprising:
a plasma enhanced chemical vapor deposition machine configured to perform the method of claim 1.

20. A method of forming graphene, the method comprising:
pre-treating a surface of a non-catalyst substrate at least partially including a material that does not catalyze growth of graphene, pre-treating including forming at least one of charges or activation sites that induce adsorption of active carbon radicals on the surface of the non-catalyst substrate; and
directly growing graphene on the pre-treated surface of the non-catalyst substrate based on injecting a reaction gas into a reaction chamber in which the non-catalyst substrate is provided, the reaction gas including a carbon source having an ionization energy equal to or less than about 10.6 eV in a plasma-enhanced chemical vapor deposition (PECVD) process.

21. The method of claim 20, wherein the pre-treating the non-catalyst substrate includes
placing the non-catalyst substrate including the pre-treated surface in the reaction chamber,
injecting a pre-treatment gas into the reaction chamber, and
supplying a bias power to the non-catalyst substrate, the bias power ranging from about 1 W to about 300 W.

22. The method of claim 21, wherein the pre-treatment gas includes at least one of inert gas, hydrogen, nitrogen, chlorine, fluorine, ammonia, or derivatives thereof.

23. The method of claim 20, wherein the growing of the graphene is performed at a processing temperature equal to or less than about 400° C.

24. The method of claim 20, wherein the plasma-enhanced chemical vapor deposition (PECVD) process utilizes a plasma that is generated based on using at least one radio frequency (RF) plasma generator or at least one microwave (MW) plasma generator.

25. The method of claim 20, wherein the non-catalyst substrate includes at least one of a Group IV semiconductor material, a semiconductor compound, or an insulating material.

26. The method of claim 25, wherein the non-catalyst substrate further includes a dopant.

27. The method of claim 20, wherein the non-catalyst substrate includes a material that includes a combination of at least two elements selected from among Si, Ge, C, Zn, Cd, Al, Ga, In, B, C, N, P, S, Se, As, Sb, and Te.

28. The method of claim 20, wherein the non-catalyst substrate includes at least one of
an oxide,
a nitride,
a carbide of at least one of Si, Ni, Al, W, Ru, Co, Mn, Ti, Ta, Au, Hf, Zr, Zn, Y, Cr, Cu, Mo, or Gd, or
a derivative thereof.

29. The method of claim 20, wherein the carbon source includes a hydrocarbon which is in a liquid state at room temperature.

30. The method of claim 20, wherein the carbon source includes at least one of
a precursor including a molecular precursor, the molecular precursor including one or more aromatic molecular rings,
a precursor including a molecule having one or more aromatic molecular rings and a functional group,
a molecular precursor including three or more aliphatic carbon bonds, or
a precursor including a functional group.

31. The method of claim 30, wherein the carbon source includes at least one of benzene, toluene, meta-xylene, propane, propene, butane, hexane, octane, cyclohexane, oxygen, nitrogen, sulfur, or phosphor.

32. The method of claim 20, wherein the reaction gas further includes at least one of an inert gas or a reducing gas.

33. The method of claim 20, wherein the graphene includes crystals having a crystal size of about 0.5 nm to about 100 nm.

34. The method of claim 20, wherein the directly growing the graphene is performed at a pressure that is equal to or less than about 10 Torr.

35. An apparatus, comprising:
a plasma enhanced chemical vapor deposition machine configured to perform the method of claim 20.
